(19) United States
(12) Patent Application Publication
(10) Pub. No.: US 2016/0192533 A1
(43) Pub. Date: Jun. 30, 2016

(54) Packaging Structure and Optical Module Using the Same

(71) Applicant: InnoLightTechnology Corporation, Suzhou (CN)

(72) Inventors: Xigui Fang, Suzhou City (CN); Kewu Wang, Suzhou City (CN); Jinming Guo, Suzhou City (CN); Xinjun Zhou, Suzhou City (CN); Xiangzhong Wang, Suzhou City (CN)

(21) Appl. No.: 14/699,703

(22) Filed: Apr. 29, 2015

(30) Foreign Application Priority Data
Dec. 26, 2014 (CN) 201410824182.4

(51) Int. Cl. H05K 7/20; H05K 1/18

(52) U.S. Cl. CPC H05K 7/205; H05K 1/181

(57) ABSTRACT

A packaging structure and an optical module using the same are disclosed, wherein said packaging structure includes: a printed circuit board, having a first surface and a second surface opposite to each other; a heat dissipation hole running through the first and second surfaces of the printed circuit board; a heat dissipation block fixed within the heat dissipation hole; a power device provided on the first surface of the printed circuit board, wherein the power device is in a thermal conductive connection with the heat dissipation block. No adhesive or other dielectric of low heat conductivity coefficient is necessary during the manufacturing process of the heat dissipation block. The heat dissipation hole can open wider, as the fixation of copper paste and the heat dissipation hole are not a concern. Therefore, the heat dissipation ability of the packaging structure is optimized and the stable operation of the device is ensured.

### CROSS REFERENCE TO RELATED APPLICATION

This application claims the priority benefit of Chinese Patent Application No. 201410824182.4, filed on Dec. 26, 2014, the contents of which are incorporated by reference herein in their entirety for all purposes.

### TECHNICAL FIELD

The present application relates to the field of optical communication component manufacturing, more particularly, to a packaging structure and an optical module using the same.

### BACKGROUND

As 4G telecommunication quickly develops and the application for cloud computing increases, the market need for high-speed optical module grows fast. Take 100G optical module for example, its power dissipation is improved greatly compared to 40G optical module, but heat generated per unit area also sharply increases if it employs a packaging of the same size as 40G optical module. In this case, its optic-electric/electric-optic transducing circuit that is sensitive to temperature may easily encounter performance degradation or even malfunction.

In the packaging method for a conventional 40G optical module, COB (chip on board) SMD bonding technique is commonly used to reduce the packaging costs. The surface of the unpacked chip is used for gold wire bonding and cannot be used for heat dissipation. Therefore, heat dissipation can only be achieved through the lower surface of PCB. To ensure the quality of high-speed signal, unpacked chips is usually surrounded by wire bonding pad, which limits the heat dissipation area. Moreover, intensive copper-filled through-holes are used as heat conduction means to conduct heat generated by power device on the PCB board to the back of the PCB board, where heat dissipation metal blocks are bonded for heat dissipation. Consequential defects include 1) the tolerance capacity of the existing technology requires that a welding ring has a width of at least 3-4 mil on each side of a drilling through hole in designing the through hole, with the minimum drilling hole diameter being 0.15 mm, i.e., the ratio of effective sectional area for heat dissipation to occupied PCB area is less than ¼; and 2) copper paste with certain proportion of adhesive is used in copper filling, which has a heat conductivity coefficient smaller than pure copper. As a result, the heat dissipation performance is compromised. Therefore, heat dissipation structure with higher efficiency is needed in packaging high-speed optical module to ensure the stable operation of the device.

### SUMMARY

According to one aspect of the present disclosure, a packaging structure is provided, wherein the packaging structure includes:

a printed circuit board, including a first surface and a second surface opposite to each other;

a heat dissipation hole running through the first surface and the second surface of the printed circuit board;

a heat dissipation block fixed within the heat dissipation hole; and

a power device provided on the first surface of the printed circuit board, wherein the power device is in a thermal conductive connection with the heat dissipation block.

In one embodiment of the present disclosure, the opening area of the heat dissipation hole on the first surface is smaller than its opening area on the second surface, and the heat dissipation block fits into the heat dissipation hole.

In yet another embodiment of the present disclosure, the heat dissipation block comprises a first heat dissipation block and a second heat dissipation block connected to each other, wherein the first heat dissipation block has a sectional area smaller than that of the second heat dissipation block and the power device is provided on the first heat dissipation block.

In another embodiment of the present disclosure, a first heat dissipation layer connected to the heat dissipation block is provided on the first surface of the printed circuit board, and the power device is connected to the heat dissipation block through the first heat dissipation layer.

In yet another embodiment of the present disclosure, a second heat dissipation layer connected to the heat dissipation block is provided on the second surface of the printed circuit board.

In another embodiment of the present disclosure, the heat dissipation block is fixed on the inner wall of the heat dissipation hole by filling adhesive.

In yet another embodiment of the present disclosure, the opening area of the heat dissipation hole has a minimum value at the first surface.

Another aspect of the present disclosure provides a packaging structure, including:

a printed circuit board, including a heat dissipation layer and a dielectric layer laminated together;

a heat dissipation hole running through the dielectric layer;

a heat dissipation block fixed within the heat dissipation hole;

a power device provided on the heat dissipation layer.

In one of the embodiments, the opening area of the heat dissipation hole close to a heat dissipation layer side is smaller than the opening area of the heat dissipation hole on the opposite side, and the heat dissipation block fits into the heat dissipation hole.

Another aspect of the present disclosure provides an optical module including any of the packaging structures.

Compared to prior art, in the present disclosure, the heat dissipation block can be pre-made in accordance with the shape of the heat dissipation hole, as the heat dissipation block is to be fixed within the heat dissipation hole. No adhesive or other dielectric of low heat conductivity coefficient is necessary during the manufacturing process of the heat dissipation block. In addition, the heat dissipation hole can open wider, as there the fixation of copper paste and the heat dissipation hole is not a concern, rendering a larger bulk of the heat dissipation block with a larger heat dissipation area. As a result, the heat dissipation ability of the packaging structure is optimized and the stable operation of the device is ensured.

### BRIEF DESCRIPTION OF THE DRAWINGS

FIG. 1 shows a schematic diagram of the packaging structure connected to the printed circuit board within the optical module, according to the first embodiment of the present disclosure.

FIG. 2 shows a sectional view of the packaging structure according to the first embodiment of the present disclosure.

FIG. 3 shows a sectional view of the heat dissipation hole of the packaging structure without the heat dissipation block within the heat dissipation hole, according to the first embodiment of the present disclosure.

FIG. 4 shows a sectional view of the heat dissipation block in the packaging structure according to the first embodiment of the present disclosure.

FIG. 5 shows a sectional view of the packaging structure according to one of the examples of the present disclosure.

FIG. 6 shows a sectional view of the heat dissipation hole of the packaging structure without the heat dissipation block within the heat dissipation hole, according to one of the examples of the present disclosure.

FIG. 7 shows a sectional view of the heat dissipation block in the packaging structure according to one of the examples of the present disclosure.

FIG. 8 shows an explosive view of the optical module using the packaging structure according to the first embodiment of the present disclosure.

FIG. 9 shows a sectional view of the packaging structure according to the second embodiment of the present disclosure.

FIG. 10 shows a sectional view of the heat dissipation hole of the packaging structure without the heat dissipation block within the heat dissipation hole, according to the second embodiment of the present disclosure.

FIG. 11 shows an explosive view of the optical module using the packaging structure according to the second embodiment of the present disclosure.

FIG. 12 shows a sectional view of the packaging structure according to the third embodiment of the present disclosure.

FIG. 13 shows a sectional view of the heat dissipation hole of the packaging structure without the heat dissipation block within the heat dissipation hole, according to the third embodiment of the present disclosure.

FIG. 14 shows a sectional view of the heat dissipation block in the packaging structure according to the third embodiment of the present disclosure.

### DETAILED DESCRIPTION

The exemplary embodiments of the present disclosure will be described in details below with reference to the figures. These embodiments are for illustrative purpose only without limiting the scope of the present disclosure. Structural, process, and functional modifications and variations of the embodiments made by a person skilled in the art should be deemed as included within the scope of the present disclosure.

In multiple figures of the present disclosure, some of the structure or portions may be exaggerated in size relative to the rest for convenience of illustration. A person skilled in the art can appreciate that the purpose of the figures is demonstrating, but not limiting, the basic structure of the present disclosure.

Terms referring to spatial relative positions herein, such as on, above, under, beneath, are for illustrative purpose only in describing, for example, the relationship of a unit or feature relative to another. Those terms referring to spatial relative positions, therefore, may include other positions of a device in use or operation in addition to those positions indicated in the figures. For example, if a device in a figure is turned upside down, then a unit defined as under or beneath another unit or feature before will be on or above the later. Therefore, the term “under”, for example, may mean both under and above. A device in a figure may be oriented in other ways (e.g., rotate 90° or otherwise) and be described accordingly using the terms referring to spatial relative positions herein.

When a component or layer is referred to as “on” or “connected to” another component or layer, it may be directly on or connected to the later, or configured through a middle component or layer. On the contrary, when a component or layer is referred to as “directly on” or “directly connected to” another component or layer, there cannot be any such middle component or layer.

Moreover, terms such as “first” and “second” used in describing various components or structures only serve to distinguish one object from another, without any limitation to their scope. For example, a first surface can be called a second surface. Similarly, a second surface can be referred to as a first surface, without deviation from the scope of the present application.

See FIG. 1 for the packaging structure 10 according to the first embodiment of the present disclosure. In this embodiment, the packaging structure 10 comprises a printed circuit board 11, a heat dissipation hole 12, a heat dissipation block 13, and a power device 15. Please note that the heat dissipation block 13, as referred to in the embodiments of the present disclosure, is a blocky structure with a volume much larger than the copper in a copper plated hole and is also a heat conductor with good heat conducting efficiency. In other words, heat dissipation block 13 is different from the commonly seen copper plating in the heat dissipation hole in prior art. The volume of heat dissipation block 13 is much larger in volume than the copper plated in a hole of even the same size, due to the limitations of the current copper plating technique. In addition, the effective heat dissipation area obtained by installing a heat dissipation block per unit area of a circuit board is far larger than setting up multiple copper-plated holes per unit area. Moreover, compared to a heat dissipation block 13 made of pure copper (i.e., a copper block), the copper for the purpose of heat dissipation obtained by copper plating is lower in heat dissipation efficiency than a heat dissipation block 13 due to its compactness and composition (copper used in copper plating contains adhesive of low heat conductivity coefficient).

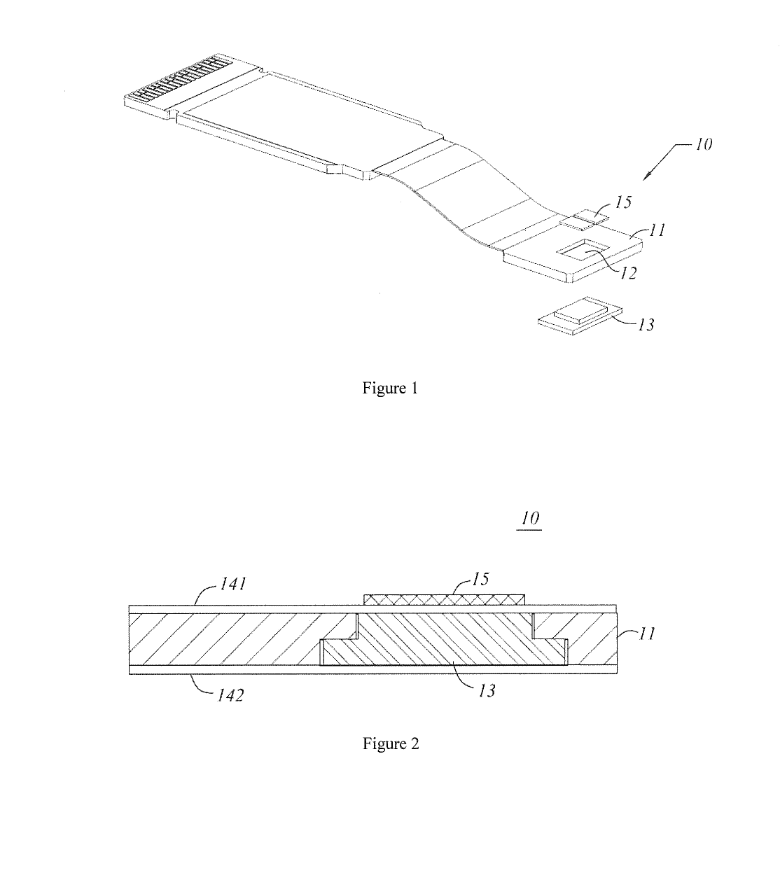

See FIGS. 2 to 4. A printed circuit board 11 comprises a first surface 111 and a second surface 112 opposite to each other, with a heat dissipation hole 12 running through the first surface 111 and the second surface 112 of the printed circuit board 11. A heat dissipation block 13 is fixed within the heat dissipation hole 12, wherein the heat dissipation block 13 fits into the heat dissipation hole 12. The term “fit” used herein means substantially the same in shape and size. The heat dissipation block can be pre-made in accordance with the shape of the heat dissipation hole, as the heat dissipation block is to be fixed within the heat dissipation hole. No adhesive or other dielectric of low heat conductivity coefficient is necessary during the manufacturing process of the heat dissipation block. In addition, the heat dissipation hole can open wider, as there the fixation of copper paste with the heat dissipation hole is not a concern. As a result, the heat dissipation ability of the packaging structure is optimized and the stable operation of the device is ensured.

A power device 15 is arranged on the first surface 111 of the printed circuit board 11 and in a thermal conductive connection to the heat dissipation block 13. “Power device” used herein is, for example, an optic-electric/electric-optic transducing component and relevant components required in the drive and amplification circuit for driving the optic-electric/electric-optic transducing component. The power device 15 is not necessarily a separate unit, but may be integrated on a chip. Obviously, it may also be multiple separate units arranged on heat dissipation block 13.

In this embodiment, a first heat dissipation layer 141 is provided on the first surface 111 of the printed circuit board 11, and the power device 15 is in thermal conductive connection with the heat dissipation block 13 through the first heat dissipation layer 141. The reason for this configuration is that, in the embodiment above where the power device 15 is directly arranged on the first surface 111 of the printed circuit board 11 and in thermal conductive connection with the heat dissipation block 13, highly precise alignment between the power device 15 and the heat dissipation hole 12 is required to ensure a reliable thermal contact between the power device 15 and the heat dissipation block 13. Therefore, it requires even higher precision in the packaging process. However, in this embodiment, by plating a first heat dissipation layer 141 on the first surface 111 of the printed circuit board 11, the power device 15, when installed on the first surface 111 of the printed circuit board 11, is in direct contact with the first heat dissipation layer 141. Meanwhile, as the first heat dissipation layer 141 is in sufficient contact with the heat dissipation block 13 at the opening 121 of the heat dissipation hole 12 on the first surface 111 of the printed circuit board 11, the heat dissipated by the power device 15 can be absorbed by the heat dissipation block 13 through conduction of the first heat dissipation layer, without requiring the power device 15 to be aligned with the heat dissipation hole 12, therefore reducing the difficulty of the packaging process. In other words, even if the power device 15 is not arranged right above the heat dissipation block 13 but deviated therefrom due to the overall arrangement, good heat dissipation can be achieved through the first heat dissipation layer 131. Moreover, the first heat dissipation layer 141 can be designed into various suitable shapes as needed. As a result, when the power devices 15 with complex or irregular shapes are used in some embodiments, the heat dissipation block 13 has no need to be designed into shapes matching with the shapes of the power devices 15, allowing the design of heat dissipation block 13 to be more regular and simple and its connection to the heat dissipation block 13 to be more reliable.

A second heat dissipation layer 142 in connection with the heat dissipation block 13 is provided on the second surface 112 of the printed circuit board 11. The second heat dissipation layer 142 further increases the heat dissipation area of the heat dissipation block 13, accelerating the dissipation of heat from the power device 15.

Of course, a person skilled in the art can appreciate that the first and second heat dissipation layers 141 and 142 may also be line layers for the printed circuit board 11.

In this embodiment, the opening area of the heat dissipation hole 12 on the first surface 111 of the printed circuit board 11 (i.e., the area of the opening 121) is smaller than the opening area of the heat dissipation hole 12 on the second surface 112 of the printed circuit board 11 (i.e., the area of the opening 122). Since the power device 15 is to be arranged on the first surface 111 of the printed circuit board 11, in embodiments using, e.g., COB (chip on board) technique for packaging, enough area needs to be reserved on the first surface 111 of the printed circuit board 11 for configuration of the power device 15. Moreover, by making the opening area of the heat dissipation hole 12 on the first surface 111 of the printed circuit board 11 smaller than that of the heat dissipation hole 12 on the second surface 112 of the printed circuit board 11, the first surface 111 of the printed circuit board 11 has enough area for setting the power device 15. Meanwhile, since the heat dissipation block 13 has a larger contact area on the side close to the second surface 112 of the printed circuit board 11, quick heat dissipation is ensured. This configuration also facilitates the installation and fixation of the heat dissipation block 13.

The opening area of the heat dissipation hole 12 has a minimum value at the first surface 111 of the printed circuit board 11. In other words, in the direction extending from the first surface 111 to the second surface 112 of the printed circuit board 11, the heat dissipation hole 12 is substantially outspreading in width.

Some detailed examples of heat dissipation hole 12 and corresponding heat dissipation block 13 are described below.

### Example 1

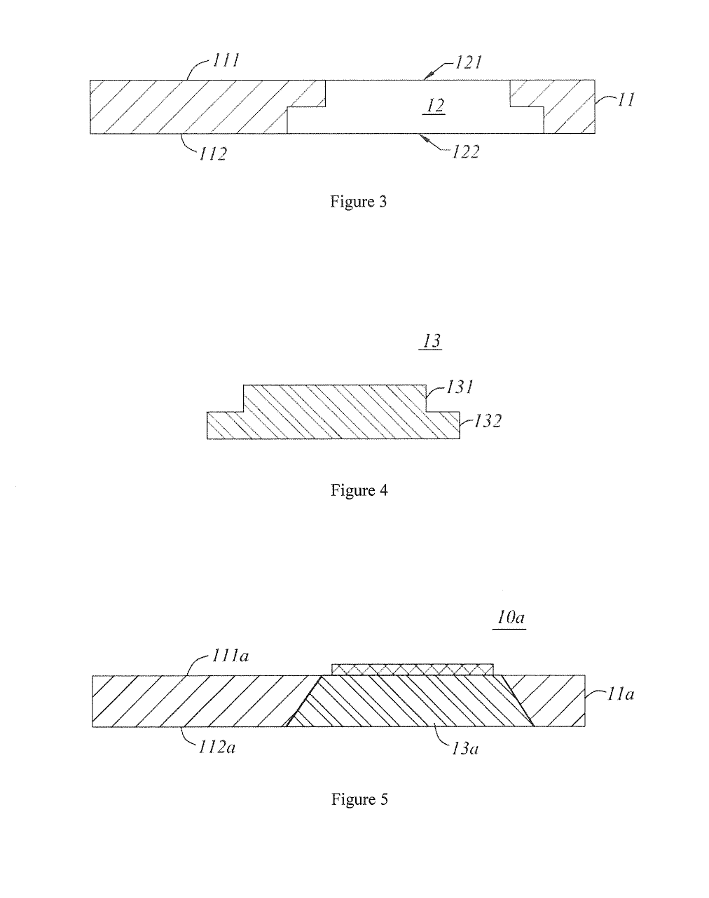

See FIGS. 3 and 4. The heat dissipation hole 12 has a T-shape section along the thickness direction of the printed circuit board 11. The heat dissipation block 13 comprises a first heat dissipation block 131 and a second heat dissipation block 132 connected to each other, wherein the sectional area of the first heat dissipation block 131 is smaller than that of the second heat dissipation block 132 in order to fit into the T-shape heat dissipation hole 12. “Sectional area” used herein means the area encompassed by heat dissipation block 13 and a plane parallel to the printed circuit board 11. Moreover, the first and second heat dissipation blocks 131 and 132 connected to each other may be manufactured separately and then connected or manufactured as a whole.

Other variations can be readily developed based on this embodiment. For example, the section of the heat dissipation hole 12 along the thickness direction of the printed circuit board 11 is benched, and the heat dissipation block 13 accordingly comprises the first, second N^{th} heat dissipation blocks connected to each other, with the sectional area of these heat dissipation blocks progressively increase in a stepwise fashion along the direction from the first surface 111 to the second surface 112 of the printed circuit board 11. Such a variation should be considered as within the scope of the disclosure.

### Example 2

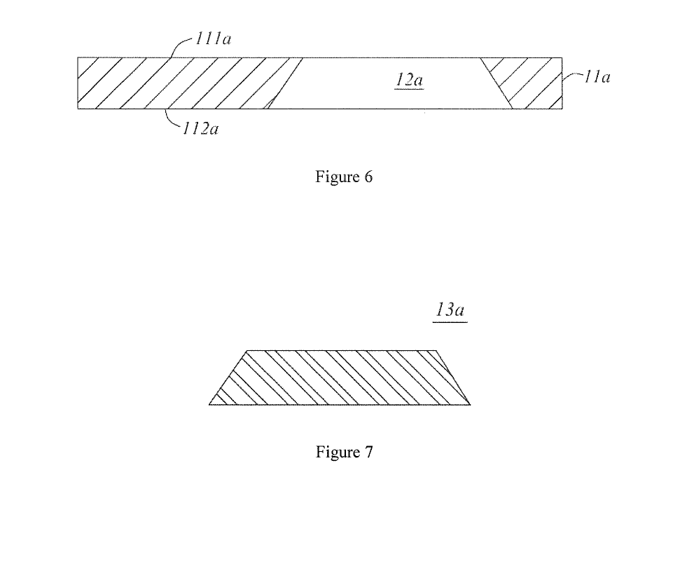

See FIGS. 5 to 7. Heat dissipation hole 12a has a trapezoidal section along the thickness direction of the printed circuit board 11a. Accordingly, the sectional area of heat dissipation block 13a progressively increase in the direction extending from the first surface 111a to the second surface 112a.

Again refer to FIGS. 1 to 4. In this embodiment, the opening 121 of the heat dissipation hole 12 on the first surface 111 fits with the power device 15. In other words, the power device 15 may be in sufficient contact with the heat dissipation block 13 through the opening 121 of the heat dissipation hole 12 on the first surface 111, in order to ensure high efficiency in heat conduction. The heat dissipation block 13 is fixed to the inner wall of the heat dissipation hole 12 by filling adhesive (not shown). The heat dissipation block 13, the first heat dissipation layer 141, and the second heat dissipation layer 142 may be made with material with good heat conduction properties, such as copper.

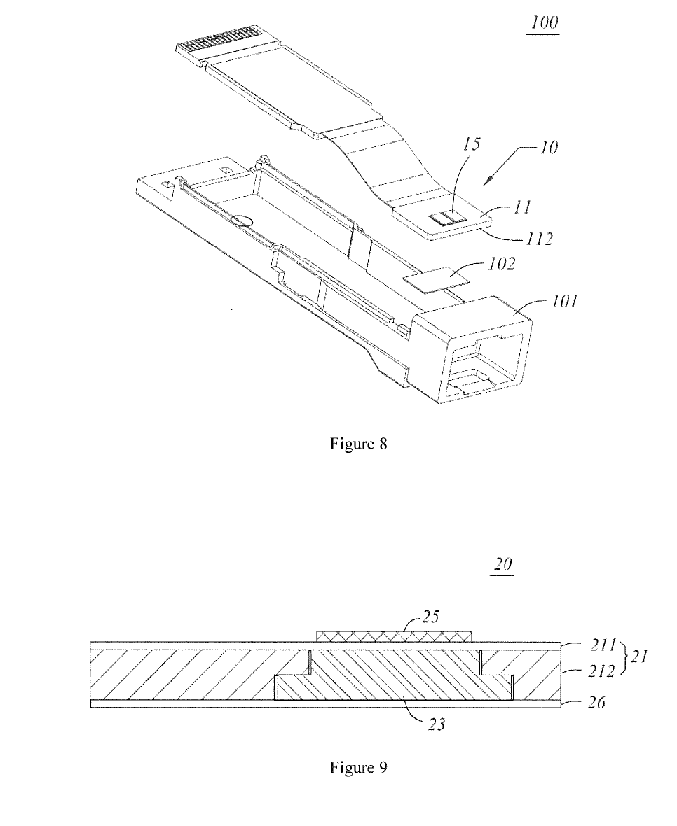

See FIG. 8. In one of the embodiments applying the optical module 100 using the packaging structure 10 according to this example, the optical module 100 comprises heat dissipation shell 101, wherein a heat dissipation plate 102 is arranged between the heat dissipation shell 101 and the second surface 112 of the printed circuit board 11 and the heat dissipation block 13 of the packaging structure 10 is in thermal conductive connection to the heat dissipation shell 101 through the heat dissipation plate 102, so that the heat generated by the power device 15 is passed on to the heat dissipation shell 101 and eventually dissipated to the atmosphere. Note that there may be thermal conductive adhesive, or thermal conductive adhesive combined with the aforementioned heat dissipation plate 102, between the heat dissipation shell 101 and the second surface 112 of the printed circuit board 11. The rest of the structure of the optical module 100 will not be further described here since they are not involved in the improvements herein.

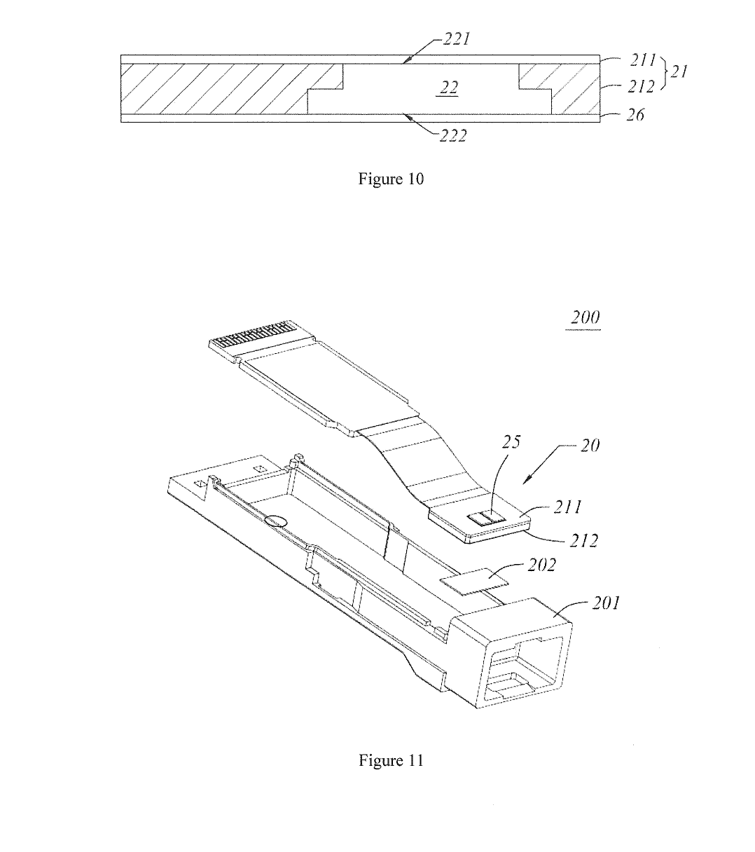

See FIGS. 9 and 10 for the packaging structure 20 according to the second embodiment of the present disclosure. In this embodiment, the packaging structure 20 comprises printed circuit board 21, heat dissipation hole 22, heat dissipation block 23, and power device 25.

The printed circuit board 21 comprises a heat dissipation layer 211 and a dielectric layer 212 laminated together. Note that “dielectric layer 212” used herein may be a single-layer structure made of a single material, or a multi-layer laminated structure, e.g., multiple laminated layers of alternating copper layers and dielectric layers. “heat dissipation layer 211” may be, for example, a copper layer on a surface of the printed circuit board 21.

The heat dissipation hole 22 runs through the dielectric layer 212 of the printed circuit board 21. The heat dissipation block 23 is fixed within the heat dissipation hole 22, wherein the heat dissipation block 23 fits with the shape of the heat dissipation hole 22, and the power device 25 is arranged on the heat dissipation layer. Similar to the embodiment above where the power device 25 is directly connected with the heat dissipation block 23, highly precise alignment between the power device 25 and the heat dissipation hole 22 is required to ensure a reliable thermal contact between the power device 25 and the heat dissipation block 23. Therefore, it requires even higher precision of the packaging process. However, in this embodiment, by arranging the power device 25 on the heat dissipation layer 211 of the printed circuit board 21, heat generated by the power device 25 can be passed on to the heat dissipation block 23, without requiring the power device 25 to be aligned with the heat dissipation hole 22, therefore reducing the difficulty of the packaging process.

In this embodiment, the opening area of the heat dissipation hole 22 close to a heat dissipation layer 211 side (i.e., the area of the opening 221) is smaller than its opening area on the opposite side (i.e., the area of the opening 222). As a result, it will not occupy too much area on the printed circuit board 21, which area can be saved for arranging the power device 25. In addition, the contact area of the corresponding heat dissipation block 23 on the opposite side can be larger, ensuring higher efficiency in heat dissipation. Similarly, a heat dissipation layer 26 in thermal conductive connection with the heat dissipation block 23 may be plated on the opposite side of the printed circuit board 21, or a heat dissipation copper layer may be laminated on the opposite side of the printed circuit board 21, in order to achieve a similar result in expending the heat dissipation contact area.

The shape of the heat dissipation hole 22 and the heat dissipation block 23 of this embodiment can be configured according to any of the previous examples, which will not be elaborated here.

See FIG. 11. In one of the examples applying an optical module 200 using the packaging structure 20 of this embodiment, the optical module 200 comprises a heat dissipation shell 201, wherein a heat dissipation plate 202 is arranged between the heat dissipation shell 201 and the dielectric layer 212 of the printed circuit board 21, and the heat dissipation block 23 of the packaging structure 20 is in thermal conductive connection to the heat dissipation shell 201 through the heat dissipation fin 202, so that heat generated by the power device 25 is passed on to the heat dissipation shell 201, and eventually dissipated to the atmosphere. Note that there may be thermal conductive adhesive, or thermal conductive adhesive combined with the aforementioned heat dissipation plate 202, between the heat dissipation shell 201 and the dielectric layer 212 of the printed circuit board 21. The rest of the structure of the optical module 200 will not be further described here since they are not involved in the improvements herein.

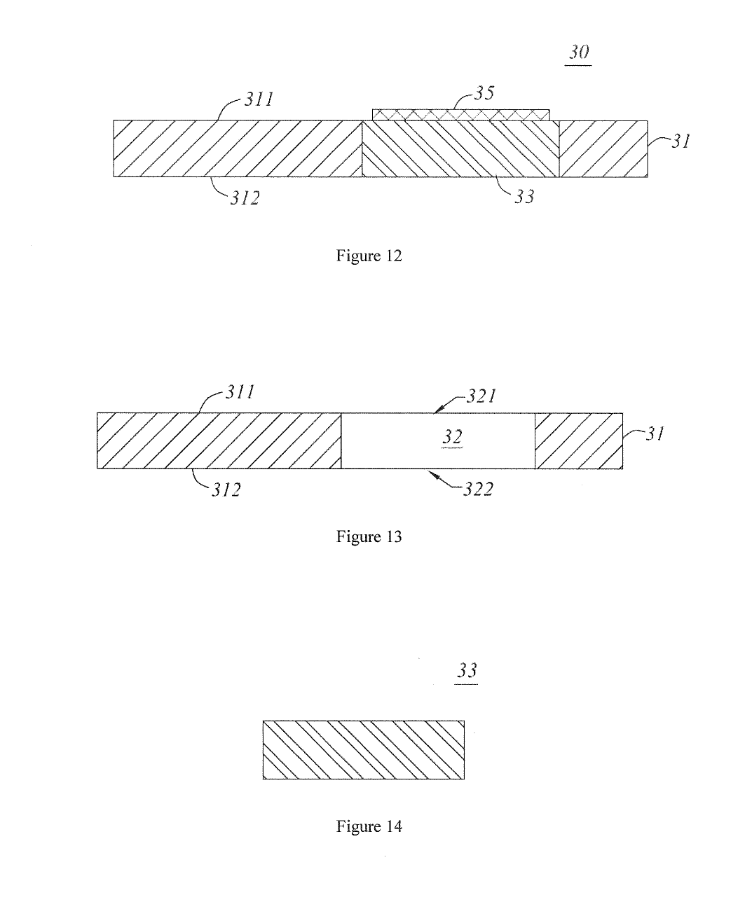

See FIGS. 12 to 14 for the packaging structure 30 according to the third embodiment of the present disclosure. In this embodiment, the packaging structure 30 comprises a printed circuit board 31, a heat dissipation hole 32, a heat dissipation block 33, and a power device 35.

The printed circuit board 31 comprises a first surface 311 and a second surface 312 opposite to each other. The heat dissipation hole 32 runs through the first surface 311 and the second surface 312 of the printed circuit board 31. The heat dissipation block 33 is fixed within the heat dissipation hole 32. Different from the example above, in this example, the opening area of the heat dissipation hole 32 on the first surface 311 (i.e., the area of the opening 321) is equal to the opening area of the heat dissipation hole 32 on the second surface 312 (i.e., the area of the opening 322). Moreover, the power device 35 is directly connected to the heat dissipation block 33 through the opening 321 of the heat dissipation hole 32 on the first surface 311 of the printed circuit board 31. Of course, there may also be, e.g., thermal conductive adhesive between the power device 35 and the heat dissipation block 33, to further increase the thermal conductive ability between the two. In this embodiment, the opening 321 of the heat dissipation hole 32 on the first surface 311 may also be designed to substantially fit with the power device 35 in order to obtain larger heat dissipation area.

The following technical effects can be achieved by the aforementioned embodiments. The heat dissipation block can be pre-made in accordance with the shape of the heat dissipation hole, as the heat dissipation block is to be fixed within the heat dissipation hole. No adhesive or other dielectric of low heat conductivity coefficient is necessary during the manufacturing process of the heat dissipation block. In addition, the heat dissipation hole can open wider, as there the fixation of copper paste and the heat dissipation hole is not a concern. The heat dissipation block, as a larger body, has a larger heat dissipation area and thus the heat dissipation ability of the packaging structure is optimized. Meanwhile, the heat dissipation hole on the printed circuit board is designed to have different opening area on each side, and the power device is arranged on the side of the printed circuit board where opening area of the heat dissipation hole is smaller than the other side, the power device being also in thermal conductive connection to the heat dissipation block through the same opening. As a result, the heat dissipation hole will not occupy too much area on the printed circuit board. And as the shape of the heat dissipation block fits with the heat dissipation hole, the contact area of the heat dissipation block on the opposite side of the printed circuit board is larger, accelerating the dissipation of heat generated by the power device and thus ensuring the stable operation of the device.

Although several examples were described in the specification, it should be appreciated that they are for the purpose of illustration only and the specification should be interpreted as a whole in order to understand the full scope of the disclosure. The technical features of the examples are not isolated from each other, but can be combined together in various ways to form other embodiments without deviating from the scope of the disclosure, which can be readily understood by a person skilled in the art.

The details described in the specification above are only illustrative of the practical embodiments of the disclosure, without limiting the scope of the disclosure. Any equivalent embodiment or its variation thereof should be deemed as within the scope of the present disclosure.

What is claimed is:

1. A packaging structure, comprising:
a printed circuit board, comprising a first surface and a second surface opposite to each other;
a heat dissipation hole running through the first surface and the second surface of the printed circuit board;
a heat dissipation block fixed within the heat dissipation hole; and
a power device provided on the first surface of the printed circuit board, wherein the power device is in a thermal conductive connection with the heat dissipation block.

2. The packaging structure according to claim 1, wherein the opening area of the heat dissipation hole on the first surface is smaller than the opening area of the heat dissipation hole on the second surface, and wherein the heat dissipation block fits into the heat dissipation hole.

3. The packaging structure according to claim 2, wherein the heat dissipation block comprises a first heat dissipation block and a second heat dissipation block connected to each other, wherein the first heat dissipation block has a sectional area smaller than that of the second heat dissipation block, and the power device is provided on the first heat dissipation block.

4. The packaging structure according to claim 1, wherein a first heat dissipation layer connected to the heat dissipation block is provided on the first surface of the printed circuit board, and the power device is in a thermal conductive connection to the heat dissipation block through the first heat dissipation layer.

5. The packaging structure according to claim 1, wherein a second heat dissipation layer connected to the heat dissipation block is provided on the second surface of the printed circuit board.

6. The packaging structure according to claim 1, wherein the heat dissipation block is fixed on the inner wall of the heat dissipation hole by filling adhesive.

7. The packaging structure according to claim 1, wherein the opening area of the heat dissipation hole has a minimum value at the first surface.

8. A packaging structure, comprising:
a printed circuit board, comprising a heat dissipation layer and a dielectric layer laminated together;
a heat dissipation hole running through the dielectric layer;
a heat dissipation block fixed within the heat dissipation hole; and
a power device provided on the heat dissipation layer.

9. The packaging structure according to claim 8, wherein the opening area of the heat dissipation hole close to a heat dissipation layer side is smaller than on the opposite side, and wherein the heat dissipation block fits into the heat dissipation hole.

10. An optical module, comprising the packaging structure according to any of the precedent claims.
